(19) United States
(12) Patent Application Publication
(10) Pub. No.: US 2016/0071910 A1
(43) Pub. Date: Mar. 10, 2016

(54) DISPLAY DEVICE

(71) Applicant: Japan Display Inc., Tokyo (JP)

(72) Inventors: Tohru SASAKI, Tokyo (JP); Toshihiro SATO, Tokyo (JP)

(21) Appl. No.: 14/830,003

(22) Filed: Aug. 19, 2015

(30) Foreign Application Priority Data
Sep. 10, 2014 (JP) 2014-184263

(51) Int. Cl. H01L 27/32

(52) U.S. Cl. CPC H01L 27/3213; H01L 27/3218; H01L 27/3244

(57) ABSTRACT

A display device having a plurality of pixels arranged in a matrix includes a first pixel arranged with a first light emitting region including a first end part, the first pixel being arranged in a first column and first row of the matrix, a second pixel arranged in adjacent in a row direction with the first pixel in a second column adjacent to the first column, the second pixel being arranged with a second light emitting region including a second end part, the first end part and second end part having a first non-parallel part, and a third pixel arranged adjacent in a column direction with the second pixel in a second row adjacent to the first row, the third pixel being arranged with a third light emitting region including a third end part, the second end part and third end part having a second non-parallel part.

### CROSS REFERENCE TO RELATED APPLICATIONS

This application is based upon and claims the benefit of priority from the prior Japanese Patent Application No. 2014-184263 filed on Sep. 10, 2014, the entire contents of which are incorporated herein by reference.

### FIELD

The present invention is related to a display device and one disclosed embodiment is related to the shape of a light emitting region between adjacent pixels arranged in a light emitting type display device.

### BACKGROUND

In recent years, the demand for high definition and low power consumption in light emitting display devices for use in mobiles has increased. Liquid crystal display devices (LCD) or light emitting display devices such as an organic EL display device which use light emitting elements (OLED: Organic Light-Emitting Diode) or electronic paper are being adopted as a display device for use in mobiles.

Among the display devices described above, for example, a light emitting display device such as an organic EL display device does not require a backlight or polarization plate that were necessary in liquid crystal display devices. Furthermore, since an organic light emitting element, has a low drive voltage, organic EL display devices are attracting significant attention as a low power consumption and thin light emitting display device. In particular, the development of upper surface emission type (referred to as top emission type) organic EL display devices which realize full color by using a white color light emitting element as a light emitting element and a color filter is progressing. Since it is possible to realize both an improvement in an aperture ratio of a pixel and high definition in the top emission type organic EL display device described above, such devices are attracting significant attention. In addition, because it is possible to form a display device just with a thin film, it is possible to realize a flexible display device. Furthermore, since a glass substrate is not used, it is possible to realize a light display device which is difficult to break and is attracting significant attention (for example, Japanese Laid Open Patent Publication No. 2002-221917).

However, in the light emitting type display device shown in Japanese Laid Open Patent Publication No. 2002-221917, since an end part (straight line part) mutually facing each other in a light emitting region of adjacent pixels is parallel, the interval between light emitting regions of adjacent pixels is narrow over a wide range. In addition, in a light emitting type display device, the light output from a light emitting element tends to be output not only in a perpendicular direction to a display surface but much of the light is output in a direction which is orthographic to an end part of a light emitting region. Therefore, in adjacent pixels, in the case where the end parts in mutually facing light emitting regions are parallel, much of the light reaches an adjacent pixel which leads to problems such as leaking light or mixed colors.

### SUMMARY

The display device having a plurality of pixels arranged in a matrix according to one embodiment of the present invention includes a first pixel arranged with a first light emitting region including a first end part, the first pixel being arranged in a first column and first row of the matrix, a second pixel arranged in adjacent in a row direction with the first pixel in a second column adjacent to the first column, the second pixel being arranged with a second light emitting region including a second end part, the first end part and second end part having a first non-parallel part, and a third pixel arranged adjacent in a column direction with the second pixel in a second row adjacent to the first row, the third pixel being arranged with a third light emitting region including a third end part, the second end part and third end part having a second non-parallel part.

### BRIEF DESCRIPTION OF DRAWINGS

FIG. 1 is a planar view diagram showing a summary of a light emitting type display device related to embodiment one of the present invention;

FIG. 2 is a planar view diagram showing a layout of a pixel in a light emitting type display device related to embodiment one of the present invention;

FIG. 3 is a cross-sectional diagram of the line A-B in the a light emitting type display device shown in FIG. 2;

FIG. 4 is a planar view diagram showing a layout of a pixel in a light emitting type display device related to an a modified example 1 in embodiment one of the present invention;

FIG. 5 is a planar view diagram showing a layout of a pixel in a light emitting type display device related to a modified example 2 in embodiment one of the present invention;

FIG. 6 is a planar view diagram showing a layout of a pixel in a light emitting type display device related to a modified example 3 in embodiment one of the present invention;

FIG. 7 is a planar view diagram showing a layout of a pixel in a light emitting type display device related to embodiment two of the present invention;

FIG. 8 is a planar view diagram showing a layout of a pixel in a light emitting type display device related to a modified example 1 in embodiment two of the present invention;

FIG. 9 is a planar view diagram showing a layout of a pixel in a light emitting type display device related to a modified example 2 in embodiment two of the present invention;

FIG. 10 is a planar view diagram showing a layout of a pixel in a light emitting type display device related to embodiment three of the present invention;

FIG. 11 is a planar view diagram showing a layout of a pixel in a light emitting type display device related to embodiment four of the present invention;

FIG. 12 is a planar view diagram showing a layout of a pixel in a light emitting type display device related to embodiment five of the present invention;

FIG. 13 is a planar view diagram showing a layout of a pixel in a light emitting type display device related to a modified example 1 in embodiment five of the present invention;

FIG. 14 is a planar view diagram showing a layout of a pixel in a light emitting type display device related to a modified example 2 in embodiment five of the present invention; and

FIG. 15 is a planar view diagram showing a layout of a pixel in a light emitting type display device of a comparative example.

### DESCRIPTION OF EMBODIMENTS

Each embodiment of the present invention is explained below while referring to the diagrams. Furthermore, the disclosure is merely an example and appropriate modifications could be easily conceived of by a person ordinarily skilled in the art while maintaining the object of the invention and are obviously included in the scope of the present invention. In addition, in order to further clarify explanation, the diagrams are only examples, are sometimes represented schematically such as the width, thickness and shape of each component compared to actual components and should not limit an interpretation of the present invention. In addition, in the specification and each diagram, components that have been described in previous diagrams are attached with the same reference symbols and a detailed explanation is sometimes omitted. A purpose of the present invention in the embodiments below is to provide a light emitting type display device which can control the occurrence of leaking light of mixed colors between adjacent pixels.

### Embodiment One

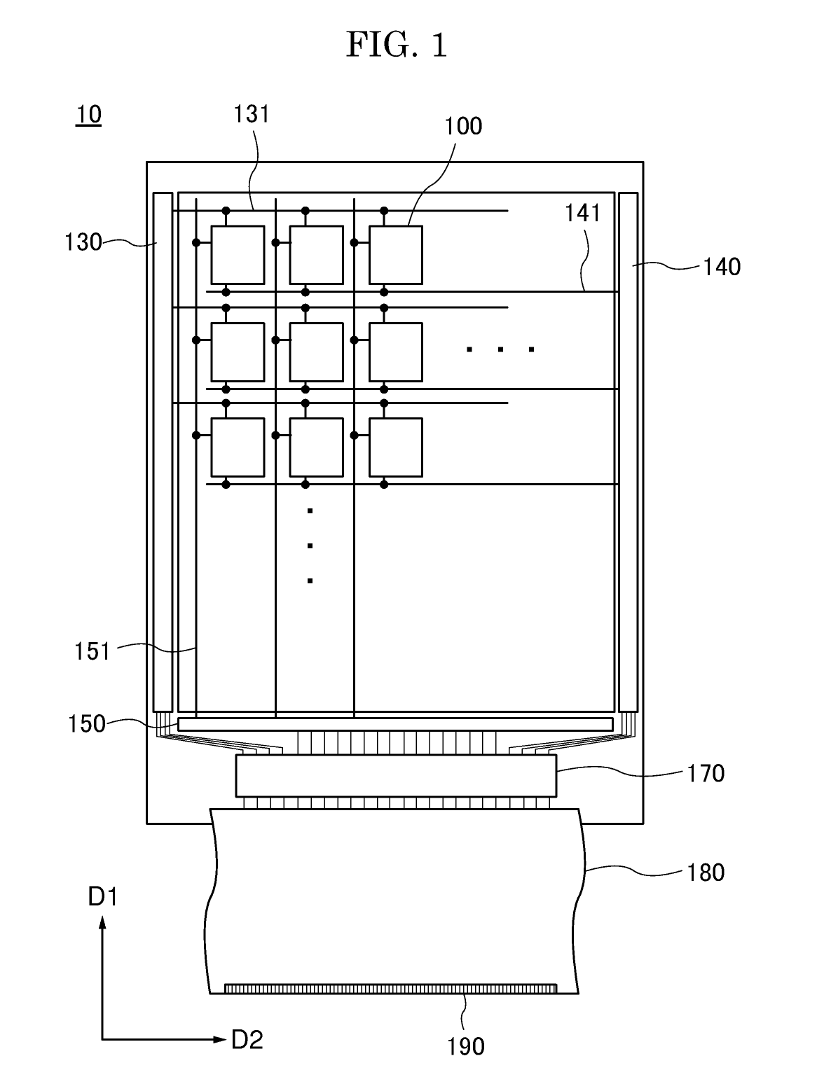

A summary, pixel layout and cross-sectional structure of a light emitting type display device 10 related to embodiment one of the present invention is explained using FIG. 1 to FIG. 3. The display device 10 in embodiment one uses a white color light emitting material as a light emitting element and a color filter, thereby, a top emission type organic EL display device is formed with full color filter (referred to as [white color+CF structure]).

### [Summary of the Display Device 10]

FIG. 1 is a planar view diagram showing a summary of a display device related to embodiment one of the present invention. In FIG. 1, only a transistor array substrate arranged with a transistor and wiring is shown. A transistor array substrate is arranged with a pixel 100 in a matrix shape with M rows and N columns (M and N are natural numbers) and each pixel 100 is controlled by a gate driver circuit 130, an emission driver circuit 140 and a data driver circuit 150.

Here, the gate driver circuit 130 is a driver circuit which selects a row for performing data writing. The gate driver circuit 130 is arranged corresponding to each pixel 100 and is connected to a data line 131 extending in a second direction D2. The emission driver circuit 140 is a drive circuit which controls the light emitted by a light emitting element arranged in a pixel. The emission driver circuit 140 is arranged corresponding to each pixel and is connected to an emission control line extending in the second direction D2. The data driver circuit 150 is a driver circuit which supplies gradation data to each pixel via a data line 151 extending in a first direction D1. Here, gradation data is supplied in sequence to a pixel selected by the gate driver circuit and emission driver circuit.

The gate driver circuit 130, emission driver circuit 140 and data driver circuit 150 are each connected to a driver IC 170 via wiring respectively. The driver IC 170 is connected to a FPC 180. An external terminal 190 for connecting to external devices is arranged in the FPC 180. In FIG. 1, although the gate driver circuit 130, emission driver circuit 140 and data driver circuit 150 are all shown connected to the driver IC 170, the present invention is not limited to this structure. For example, a part or all of the drivers may also be connected to the FPC 180 without using the driver IC 170.

### [Pixel Layout of the Display Device 100]

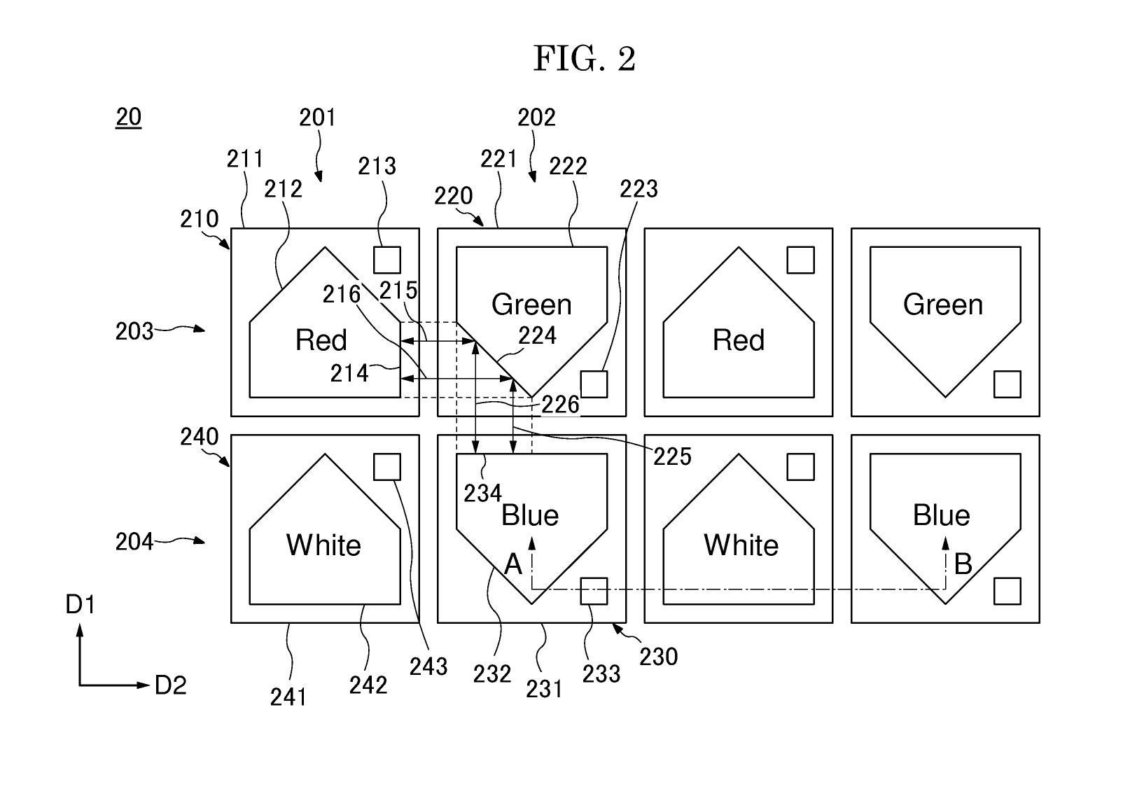

FIG. 2 is a planar view diagram showing a layout of a pixel in the display device related to embodiment one of the present invention. FIG. 2 explains a pixel layout 20 exemplifying a typical pixel in 2 rows and 4 columns among the pixel layout of the display device 10. FIG. 2 explains a light emitting region of each pixel having a rotational symmetrical shape or roughly the same (a substantially same) pentagon shape, and a layout in which four pixels each emit light in different colors are counted as one unit. Here, one unit indicates a different light emitting color pixel necessary for realizing full color.

In a light emitting type display device arranged with a plurality of pixels in a matrix shape, a pixel layout 20 includes a first pixel 210 arranged in a first column 201 and first row 203 of the matrix, a second pixel 220 arranged adjacent in a row direction (D2 direction) to the first pixel 210 in a second column 202 adjacent to the first column 201, a third pixel 230 arranged adjacent in a column direction (D1 direction) to the second pixel 220 in a second row 204 adjacent to the first row 203, and a fourth pixel 240 arranged in the first column 201 and third row 204.

A first pixel electrode 211, first light emitting region 212 and first contact hole 213 are arranged in the first pixel 210. In addition, a second pixel electrode 221, second light emitting region 222 and second contact hole 223 are arranged in the second pixel 220. In addition, a third pixel electrode 231, third light emitting region 232 and third contact hole 233 are arranged in the third pixel 230. In addition, a fourth pixel electrode 241, fourth light emitting region 242 and fourth contact hole 243 are arranged in the fourth pixel 240

Here, the first light emitting region 212, second light emitting region 222, third light emitting region 232 and fourth light emitting region 242 all have a pentagon shape, that is, each light emitting region has a rotational symmetrical shape or a substantially same shape. In FIG. 2, although each light emitting region is shown combining a rectangular shape and an isosceles triangle, what is known as pentagon shape called a home base type, the present invention is not limited to this shape. For example, other pentagon shapes are possible. In addition, other polygon shapes are also possible. Here, each inner angle of the polygon may be 90 degrees or more. By setting each inner angle of a pentagon or polygon to degrees or more, it is possible to control the shape in a photolithography process or etching process from changing from a design shape.

In addition, the first end part 214 of the first light emitting region 212 and the second end part 224 of the second light emitting region 222 are non-parallel. In other words, the first end part 214 and the second end part 224 have a non-parallel part. In addition, in other words, the first end part 214 of the first light emitting region 212 and the second end part 224 of the second light emitting region 222 facing the first end part 214 in a row direction (D2 direction) are mutually non-parallel. In addition, in other words, the distances 215, 216 between the first end part 214 and the second end part 224 in different positions in a column direction (D1 direction) are mutually different.

In addition, the second end part 224 and the third end part 234 of the third light emitting region 232 are non-parallel. In other words, the second end part 224 and the third end part 234 have a non-parallel part. In addition, in other words, the second end part 224 of the second light emitting region 222 and the third end part 234 of the third light emitting region 232 facing the second end part 224 in a column direction (D1 direction) are mutually non-parallel. In addition, in other words, the distances 225, 226 between the second end part 224 and the third end part 234 in different positions in a row direction (D2 direction) are mutually different.

In addition, the first light emitting region 212, the second light emitting region 222, the third light emitting region 232 and fourth light emitting region 242 each emitting different color light. In FIG. 2, the first light emitting region 212 emits red (R), the second light emitting region 222 emits green (G), the third light emitting region 232 emits blue (B) and the fourth light emitting region 242 emits white (W). However, the light emitting type display device related to the present invention is not limited to emitting light in the four colors RGBW as in FIG. 2 and other colors may also be combined. In addition, the number of pixels included in one unit in a pixel layout is not limited to four pixels and may be three pixels or less or five pixels or more.

### [Cross-Sectional Structure of a Pixel Part in Display Device 10]

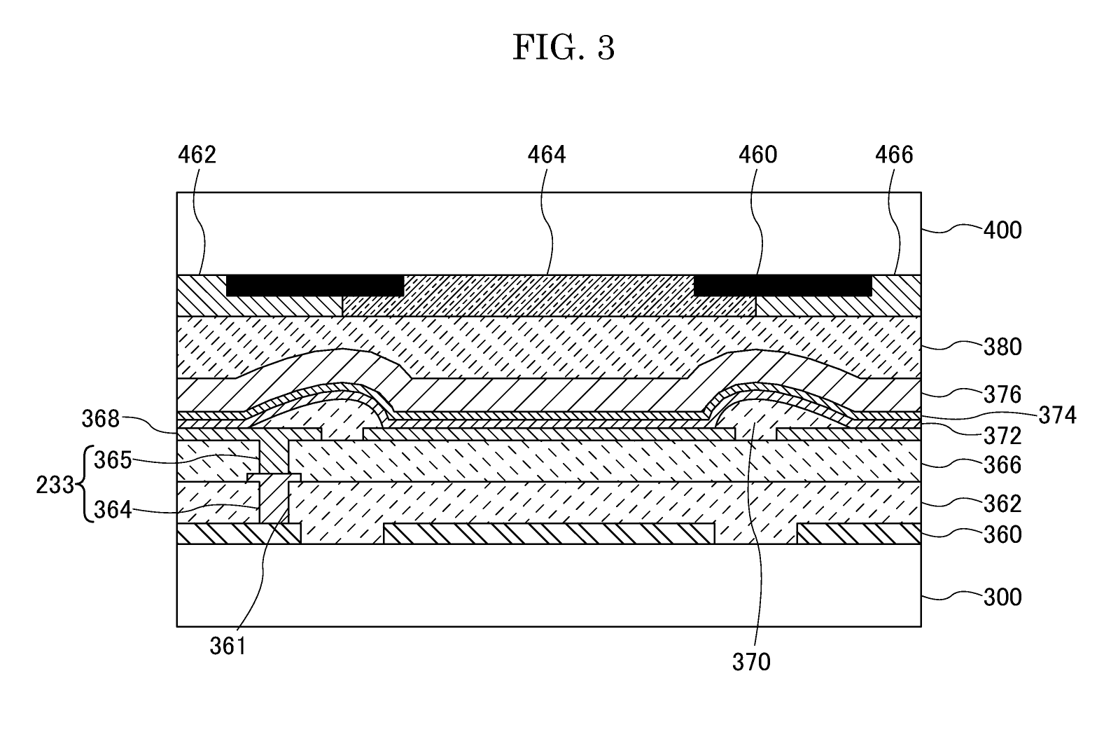

FIG. 3 is a cross-sectional diagram of the line A-B in the display device shown in FIG. 2. According to FIG. 3, the display device 10 includes a first substrate 300 and second substrate 400 mutually facing each other.

The first substrate 300 includes a transistor layer 360 arranged in each pixel in upper part of the first substrate 300, a first insulation layer 362 covering the transistor layer 360 and arranged with a first aperture part 361, an upper layer wiring layer 364 connected to the transistor layer 360 via the first aperture part 361, a second insulation layer 366 covering the upper layer wiring layer 364 and arranged with a second aperture part 365, and a pixel electrode 368 connected to the upper layer wiring layer 364 via the second aperture part 365. Furthermore, the first substrate 300 includes a separation wall 370 which sections each pixel and is arranged so as to cover a pattern end part of the pixel electrode 368, a light emitting layer 372 which outputs white light and is arranged on an upper part of the pixel electrode 368 and separation wall 370, a common electrode 374 which supplies power to the light emitting layer 372, and a protection layer 376 which has moisture prevention properties and is arranged above the light emitting layer 372 and common electrode 374.

In addition, the second substrate 400 includes a light block layer 460 arranged in a region overlapping the separation wall 370 in between adjacent pixels, and color filters 462, 464, 466 arranged corresponding to each pixel and which allow light of a specific wavelength to pass through. Here, the color filter 462 emits blue (B) light, the color filter 464 emits white (W) light and the color filter 466 emits blue (B) light.

In addition, the first substrate 300 and second substrate 400 are bonded together via a filler material 380. The filler material 380 relieves a step formed by a structure formed on the first substrate 300 and second substrate 400, and is filled between the substrates so that the first substrate 300 and second substrate 400 becomes roughly parallel. In addition, although not shown in FIG. 3, a sealing material may be arranged in the periphery of a pixel region arranged with the pixel 100 shown in FIG. 1 so as to enclose a pixel region.

The transistor layer 360 includes a transistor element and wiring. It is possible to use a generally used material as the transistor element. For example, it is possible to use a bottom gate type transistor element or top gate type transistor element using amorphous silicon, polysilicon, polycrystalline silicon, oxide semiconductor, and organic semiconductor in a channel layer of a transistor element.

It is possible to use a generally used insulation material as the first insulation layer 362. For example, in the case where an inorganic material is used as an insulation material, it is possible to use a silicon oxide film (SiOx film), silicon nitride film (SiNx film), silicon oxide nitride film (SiOxNy film), nitride oxide silicon film (SiNxOy film), aluminum oxide film (AlOx film), aluminum nitride film (AlNx film), aluminum oxide nitride film (AlOxNy film), aluminum nitride oxide film (AlNxOy film), TEOS film and the like (x and y are optional). In addition, a structure in which these films are stacked may also be used. In addition, in the case where an organic material is used as the insulation material, it is possible to use a polyimide resin, an acrylic resin, an epoxy resin, a silicon resin, a fluororesin and a siloxane resin and the like. In addition, a structure in which these films are stacked may also be used. Furthermore, a structure in which the inorganic insulation films and organic insulation films described above are stacked may also be used.

Here, the SiOxNy film and AlOxNy film are a silicon compound and aluminum compound containing a less amount of nitrogen (N) then oxygen (O). In addition, the SiNxOy film and AlNxOy film are a silicon compound and aluminum compound containing a less amount of oxygen (O) then nitrogen (N). In addition, the TEOS film indicates a CVD film with TEOS (Tetra Ethyl Ortho Silicate) as the raw material and the TEOS film has the effect of relieving a ground step and flattening.

It is possible to use a generally used conductive material as the upper layer wiring layer 364. For example, it is possible to use aluminum (Al), titanium (Ti), molybdenum (Mo), tungsten (W), tantalum (Ta), nickel (Ni), cobalt (Co), chrome (Cr), bismuth (Bi), copper (Cu), silver (Ag) and gold (Au) and the like. In addition, it is possible to use an alloy of these materials. In addition, it is also possible to use a nitride of these materials. Furthermore, it is possible to use a structure in which these films are stacked.

It is possible to use the same material as the first insulation layer 362 as the second insulation material 366. However, because the pixel electrode 368 is arranged above the second insulation layer 366, it is preferred that the surface of the second insulation layer 366 is parallel. That is, it is possible to use an organic insulation layer as the second insulation layer 366. In addition, it is possible to use an inorganic insulation layer which relieves a ground step such as the TEOS film. Furthermore, it is also possible to arrange an inorganic insulation layer as is used in the first insulation layer 362 above an organic insulation layer or TEOS film and the like. In addition, in the case where a ground step is not formed in a region in which the pixel electrode 368 is arranged, a structure is possible in which an organic insulation layer or TEOS film is not arranged as described above.

It is possible to use a material with reflective properties as the pixel electrode 368 in the case of a top emission type display device. On the other hand, it is possible to use a material with transparent properties in the case of a bottom emission type display device. It is possible to select a material with a high reflectance as the material with reflection properties, for example, it is possible to use Al, Ti, Mo, Ni, Ag or an alloy of these. In addition, a structure in which films using the materials described above are stacked may be used as the material with reflection properties. In addition, it is possible to use a conductive material with high visible light translucency, for example, it is possible ITO (Indium Oxide Tin), ZnO (Zinc Oxide), SnO₂ (Tin Oxide), In₂O₃ (Indium Oxide), IZO (Zinc Oxide added with Indium as a dopant), GZO (Zinc Oxide added with gallium as a dopant), AZO (Zinc Oxide with aluminum added as a dopant), and titanium oxide added with impurities such as Niobium (Nb) as dopants.

It is possible to use a generally used resin material as the separation wall 370 and use a photosensitive resin material. It is possible to use a photosensitive acrylic and photosensitive polyimide for example as the photosensitive resin.

It is possible to use a generally used light emitting material which emits light by current excitation or voltage excitation as the light emitting layer 372. The light emitting material may be an organic material or an inorganic material. In the case where the light emitting material is an organic material, the light emitting layer 372 may have a structure formed by a single organic EL layer which emits white light or a structure in which a plurality of organic EL layer which emits different color light are stacked. In addition, the light emitting layer 372 may also include an electron injection material, an electron transport material, a hole injection material and a hole transport material in addition to a light emitting material.

As a structure in which a plurality of organic EL layers are stacked, for example, it is possible to use a structure in which organic EL layers which output blue light and yellow light are stacked, or a structure in which organic EL layers which output blue light, green light and red light are stacked. In addition, the present invention is not limited to the structures described above. It is possible to form a light emitting layer which emits white light using a stacked structure of a plurality of color light. Here, emitted white light may be light having wavelengths of at least blue light, green light and red light and is not limited to a strict meaning of white.

It is possible to use a transparent material as the common electrode 374 in the case of a top emission type display device. On the other hand, it is possible use a material with reflective properties as the common electrode in the case of a bottom emission type display device. For example, it is possible to use ITO, ZnO, SnO₂, In₂O₃, IZO, GZO, AZO and titanium oxide added with impurities such as Nb as dopants as the material with transparent properties the same as the pixel electrode 368. In addition, it is possible to use Al, Ti, Mo, Ni, Ag or an alloy of these as the material with reflective properties the same as the pixel electrode 368. In addition, a structure is also possible in which films using the materials described above are stacked.

The protection layer 376 is arranged so as to cover at least the light emitting layer 372 and it is possible to use a material with a high blocking capability with respect to water and impurities. For example, it is possible to use a SiNx film, SiOx film, SiNxOy film, SiOxNy film, AlNx film, AlOx film, AlOxNy film and AlNxOy film and the like (x and y are optional). In addition, a structure is also possible in which these films are stacked.

Here, a barrier layer which controls dispersion of impurities from the first substrate 300 into the transistor layer 360 may be arranged between the first substrate 300 and the transistor layer 360. It is possible to use a SiNx film, SiOx film, SiNxOy film, SiOxNy film, AlNx film, AlOx film, AlOxNy film and AlNxOy film and the like the same as the protection layer 376 described above (x and y are optional). In addition, a structure is also possible in which these films are stacked.

It is possible to use a generally used material with a high absorption ratio with respect to visible light as the light shielding layer 460. A metal material such as Cr and the like may be used and a resin material colored with black may also be used as the light shielding layer 460. The light shielding layer 460 is arranged in a display region in which a pixel is arranged and a periphery region in which a drive circuit is arranged. The light shielding layer 460 is arranged so as to overlap wiring and transistors in a region which sections each pixel in the display region. In addition, the light shielding layer 460 is arranged in a region between the display region and a sealing material in a periphery region.

A generally use material with a high transparency in a certain single color of light may be used for the color filters 462, 464, 466. For example, it is possible to use a material with a high transparency in each color RGB in a pixel which display RGB as a color filter. In addition, a material which has a high transparency of a desired white light component in a pixel which emits W and can adjust the chromaticity of light output from the light emitting layer 372.

Although a structure is shown in FIG. 3 in which adjacent color filters do not mutually overlap, the present invention is not limited to this structure. A structure is also possible in which adjacent color filters mutually overlap. In the case where adjacent color filters mutually overlap, it is preferred that the overlapping sections are designed so be located in a region arranged with the light shielding layer 460. In addition, although the light shielding layer 460 is arranged between the second substrate 400 and the color filters 462, 464, 466 in FIG. 3, the present invention is not limited to this structure. The light shielding layer 460 may also be arranged between the color filters 462, 464, 466 and the filler material 380.

As described above, according to the light emitting display device related to embodiment one, by arranging the first end part 214 of the first light emitting region 212 and the second end part 224 of the second light emitting region 222 to be non-parallel in adjacent pixels 210, 220, for example, among the light output from the first end part 214, it is more difficult for the light which passes through the distance 216 which is longer than the distance 215 to reach the second end part 224 than the light passing through the distance 215. Therefore, it is possible to control light output from the first end part 214 reaching the second light emitting region 222. In addition, similarly, by arranging the second end part 224 and the third end part 234 of the third light emitting region 232 to be non-parallel in adjacent pixels 220, 230, for example, among the light output from the second end part 224, it is more difficult for the light which passes through the distance 226 which is longer than the distance 225 to reach the third end part 234 than the light passing through the distance 225. Therefore, it is possible to control light output from the second end part 224 reaching the third light emitting region 232. As a result, it is possible to control leaking light and mixed colors occurring between adjacent pixels. This effect is particularly more effective in the case where the color of emitted light by adjacent pixels is different.

In addition, when pixels included in one unit in a pixel layout emit light in the four colors RGBW, visibility of a pixel using W is improved. As a result, it is possible to improve the appearance of luminosity of a color represented by RGB. In addition, since each light emitting region of a pixel included in one unit in a pixel layout has a rotational symmetrical shape or a substantially same shape, in the case where the current is supplied to all pixels included in one unit, the light emitting layer of each pixel deteriorates in the same manner. Therefore, since there is no difference in the speed of deterioration due to pixels emitting light in different colors, for example, it is possible to control the problem of changing colors by a weakening of the light emitting luminosity of any of RGB.

### Modified Example of Embodiment One

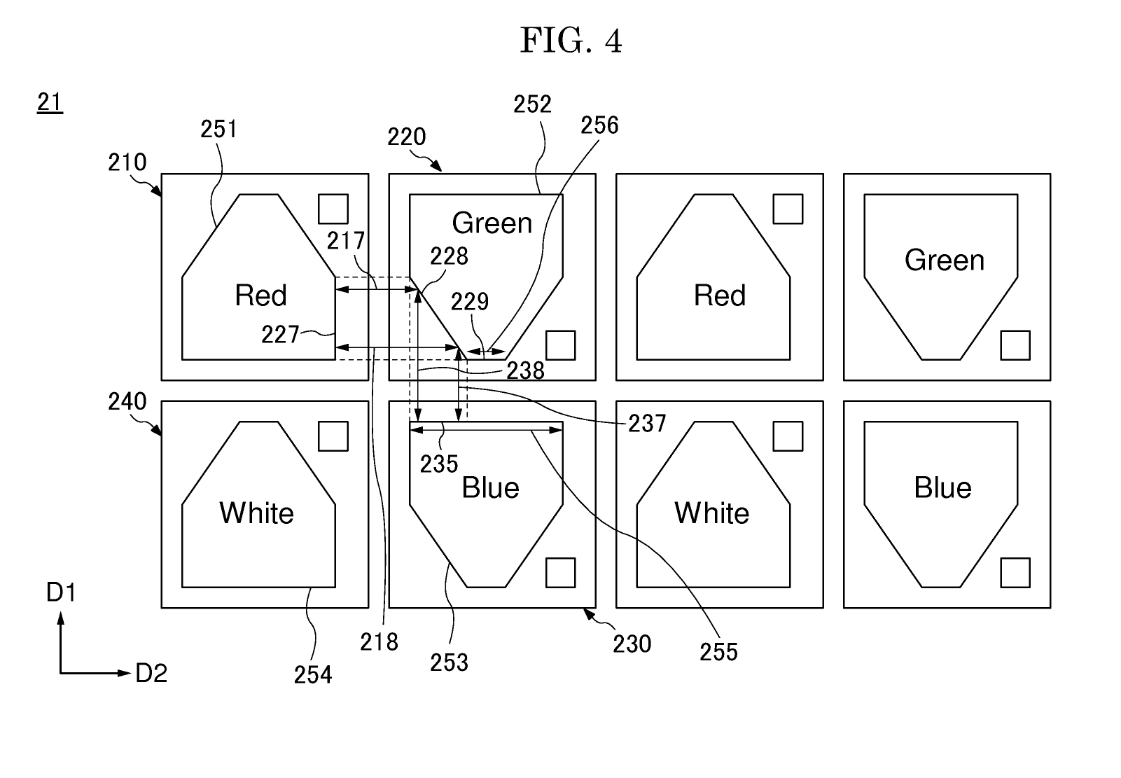

A pixel layout of a light emitting type display device related to a modified example of embodiment one of the present invention is explained using FIG. 4 to FIG. 6. In the modified example, the display device 10 explained in embodiment one is used and only the layout of a pixel is different.

FIG. 4 is a planar view diagram showing the layout of a pixel in a light emitting type display device related to a modified example one of embodiment one of the present invention. Although the pixel layout 21 shown in FIG. 4 is similar to the pixel layout shown in FIG. 2, the pixel layout 21 is different to the pixel layout 20 in that a partial parallel section is arranged in each end part of adjacent pixels.

As is shown in FIG. 4, a first light emitting region 251, second light emitting region 252, third light emitting region 253 and fourth light emitting region 254 arranged in the first pixel 210, second pixel 220, third pixel 230 and fourth pixel 240 shown in the pixel layout 21 have a hexagonal shape in which a part of the peak part of pentagon shape of each light emitting region shown in FIG. 2 is cut away. In FIG. 4, although the first to fourth light emitting regions (251 to 254) have a rotational symmetrical shape or a substantially same shape, each light emitting region may also have a different shape. Here, the hexagonal light emitting region shown in FIG. 4 has a long edge 255 and a short edge 256.

Here, the relationship between the second light emitting region 252 of the second pixel 220 and the third light emitting region 253 of the third pixel 230 shown in FIG. 4 is explained in detail. As is shown in FIG. 4, the second end part 228 of the second light emitting region 252 and the third end part 235 of the third light emitting region 253 are non-parallel, and the second end part 229 of the second light emitting region 252 and the third end part 235 of the third light emitting region 253 are parallel. In other words, the second end parts 228, 229 and the third end part 235 include a non-parallel part and parallel part. Here, the short edge 256 of the hexagonal shaped light emitting region has a length of half or less and preferably a quarter or less the length of the long edge 255. In other words, in the case where a region taken up by a non-parallel part between the second end part 228, 229 and third end part 235 and a region taken up by a parallel part between the second end part 228, 229 and third end part 235 are projected above the axis D2 in FIG. 4, the region taken up by the parallel part may by half and preferably a quarter of that of the region taken up by the non-parallel part. In addition, the length of the short edge 256 is preferred to be shorter than the distance between the second end part 229 and third end part 235.

Here, the first end part 227 of the first light emitting region 251 and the second part 228 of the light emitting region 252 are non-parallel. In other words, the first end part 227 and the second end part 228 have a non-parallel part. In addition, in other words, the first end part 227 of the first light emitting region 251 and the second end part 228 of the second light emitting region 252 facing in a row direction (D2 direction) are mutually non-parallel. In addition, in other words, the distances 217, 218 between the first end part 227 and the second end part 228 in a different position in a column direction (D1 direction) are mutually different.

In addition, the second end part 228 and the third end part 235 of the third light emitting region 253 are non-parallel. In other words, the second end part 228 and third end part 235 have a non-parallel part. In addition, in other words, the second end part 228 of the second light emitting region 252 and the third end part 235 of the third light emitting region 253 facing in a column direction (D1 direction) are mutually non-parallel. In addition, in other words, the distances 237, 238 between the second end part 228 and the third end part 235 in a different position in a row direction (D2 direction) are mutually different.

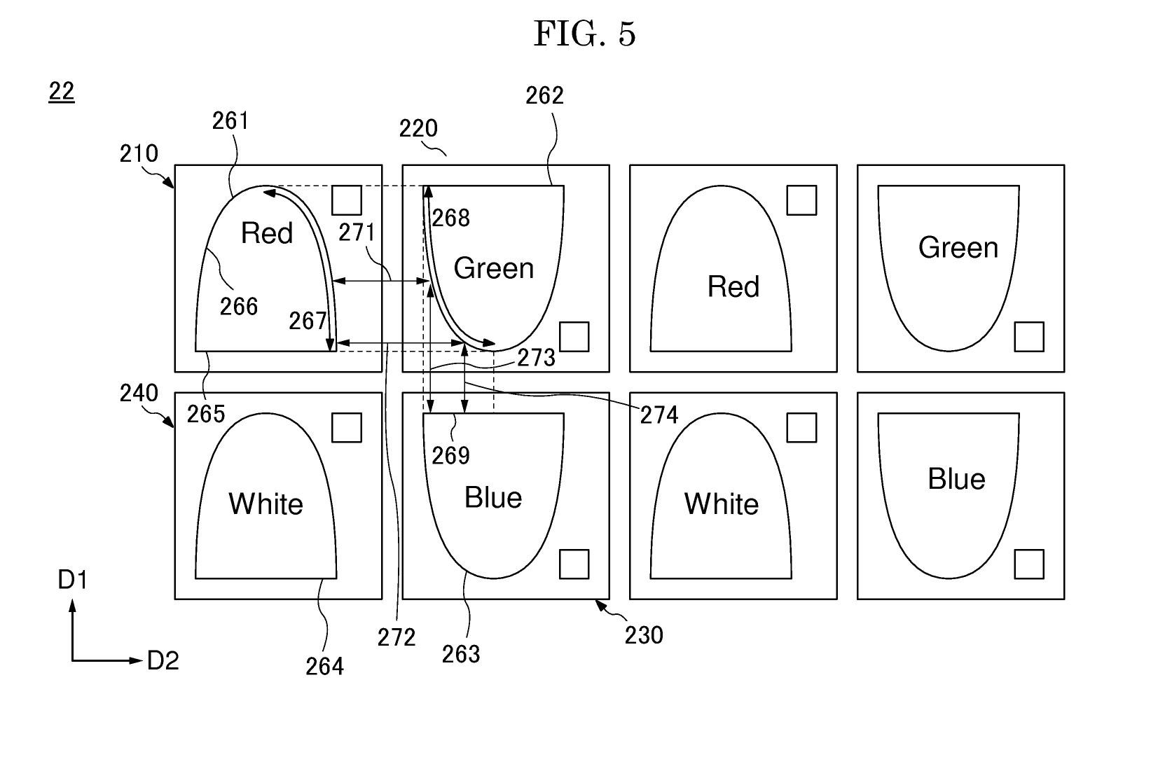

FIG. 5 is a planar view diagram showing a layout of a pixel of a light emitting type display device related to a modified example two of embodiment one of the present invention. Although the pixel layout 22 shown in FIG. 5 is similar to the pixel layout 20 shown in FIG. 2, the pixel layout 22 is different to the pixel layout 20 in that the pixel layout shape of a light emitting region in each pixel has a curved part.

As is shown in FIG. 5, the first light emitting region 261, second light emitting region 262, third light emitting region 263 and fourth light emitting region 264 arranged in the first pixel 210, second pixel 220, third pixel 230 and fourth pixel 240 each have a straight line part 265 and curved part 266. In FIG. 5, the first light emitting region 261 and fourth light emitting region 264 have a convex shaped curved part 266 in the arrow direction D1, and the second light emitting region 262 and third light emitting region 263 have a convex shaped curved part 266 in a reverse direction of the arrow D1. In FIG. 5, although the first to fourth light emitting regions (261 to 264) have a rotational symmetrical shape or a substantially same shape, each light emitting region may also have a different shape. In addition, the light emitting regions are not limited to the shape shown in FIG. 5, a part or all of light emitting region may have a convex shaped curved part in the D2 direction.

Here, the first end part 267 facing the second pixel side 220 among the curved part 266 of the first light emitting region 261 and the second end part 268 facing the first pixel side 210 among the curved part 226 of the second light emitting region 262 are non-parallel. In other words, the first end part 267 and second end part 268 are non-parallel. In addition, in other words, the first end part 267 of the first light emitting region 261 and the second end part 268 of the second light emitting region 262 facing in a row direction (D2 direction) are mutually non-parallel. In addition, in other words, the distances 271, 272 between the first end part 267 and the second end part 268 in a different position in a column direction (D1 direction) are mutually different.

In addition, the second end part 268 which is a part of the end part facing the third pixel 230 side among the curved part 266 of the second light emitting region, and the third end part 269 which is a straight line part of the third light emitting region 263 are non-parallel. In other words, the second end part 268 and third end part 269 have non-parallel parts. In addition, in other words, the second part 268 of the second light emitting region 262 and the third end part 269 of the third light emitting region 263 facing in a column direction (D1 direction) are mutually non-parallel. In addition, in other words, the distances 273, 274 between the second end part 268 and the third part 269 in a different position in a row direction (D2 direction) are mutually different.

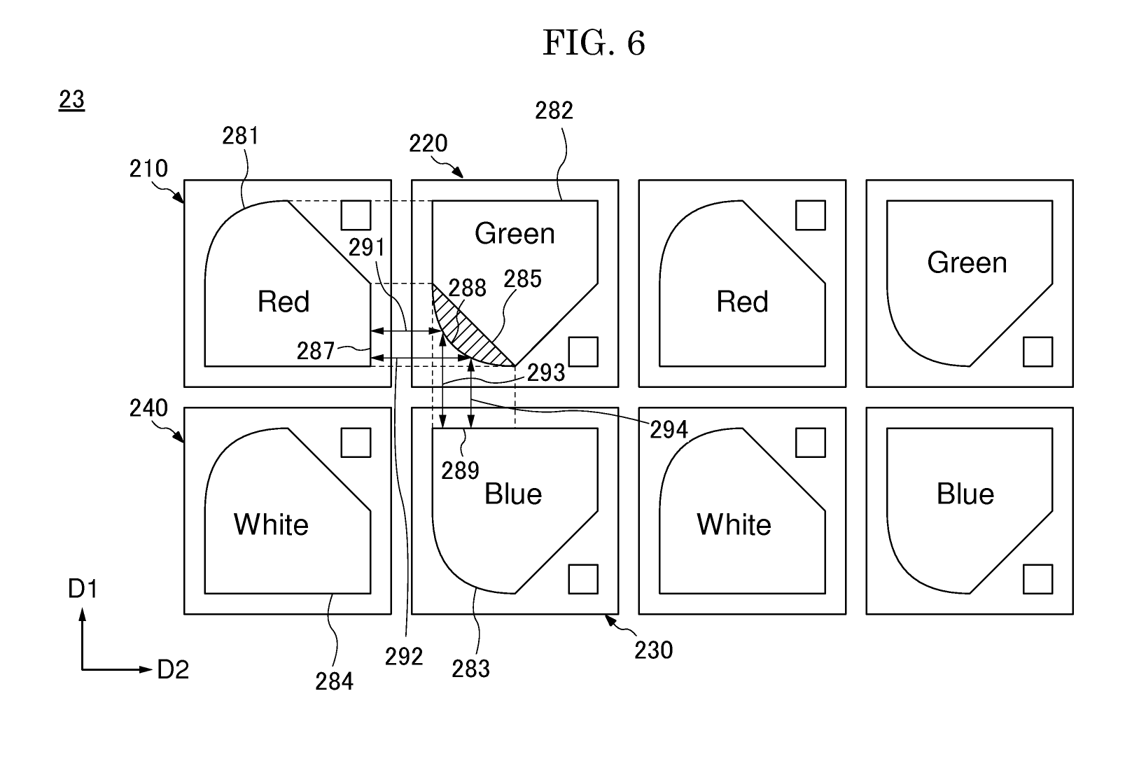

FIG. 6 is a planar view diagram showing a layout of a pixel in a light emitting type display device related to a modified example 3 related to embodiment one of the present invention. Although the pixel layout 23 shown in FIG. 6 is similar to the pixel layout 20 shown in FIG. 2, the pixel layout 24 is different in that a part of the light emitting region of the pixel layout 20 includes a curve.

As is shown in FIG. 6, the first light emitting region 281, second light emitting region 282, third light emitting region 283 and fourth light emitting region 284 arranged in the first pixel 210, second pixel 220, third pixel 230 and fourth pixel 240 shown in the pixel layout 23 have a shape in which a part of the end part of the pentagon of each light emitting region shown in FIG. 2 is a curved shape. In FIG. 6, although the first to fourth light emitting regions (281 to 284) have a rotational symmetrical shape or roughly similar shape, each light emitting region may also have different shapes. As described above, when a part of an end part is a curved shape, the light emitting region in FIG. 6 has a wider area by the amount of the shaded part 285 compared to the light emitting region in FIG. 2.

Here, the first end part 287 facing the second pixel 220 side of the first light emitting region 281 and the curved shape second end part 288 of the second light emitting region 282 are non-parallel. In other words, the first end part 287 and second end parts 288 have non-parallel parts. In addition, in other words, the first end part 287 of the first light emitting region 281 and the second end part 288 of the second light emitting region 282 facing in a row direction (D2 direction) are mutually non-parallel. In addition, in other words, the distances 291 and 292 between the first end part 287 and the second end part 288 in a different position in a column direction (D1 direction) are mutually different.

In addition, the curved shape second end part 288 of the second light emitting region 282 and the third end part 289 of the third light emitting region 283 are non-parallel. In other words, the second end part 288 and third end part 289 have non-parallel parts. In addition, in other words, the second end part 288 of the second light emitting region 282 and the third end part 289 of the third light emitting region 283 facing in a column direction (D1 direction) are mutually non-parallel. In addition, in other words, the distances 293 and 294 between the second end part 288 and the third end part 289 in a different position in a row direction (D2 direction) are mutually different.

As described above, according to the light emitting type display device related to the modified examples of embodiment one, when pairs of end parts of each light emitting region in adjacent pixels 210, 220 and adjacent pixels 220, 230 are non-parallel, it is possible to control light output from a light emitting region of the pixel 220, for example, from reaching the light emitting region of the first pixel 210 or third pixel 230. As a result, it is possible to control leaking light or mixed colors occurring between adjacent pixels.

### Embodiment Two

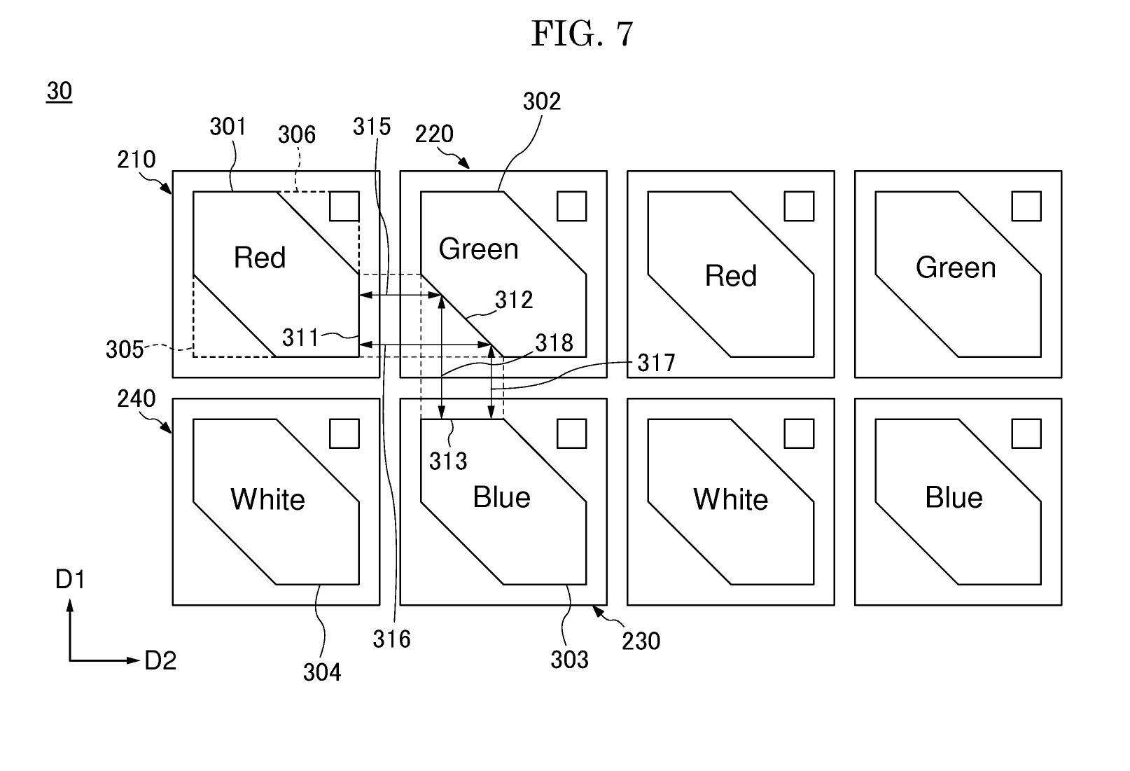

A pixel layout 30 of a light emitting type display device related to embodiment two of the present invention is explained using FIG. 7. Furthermore, the [white+CF structure] can be used for the light emitting type display device related to the embodiment two the same as the display device 10 shown in FIG. 1.

### [Pixel Layout]

FIG. 7 is a planar view diagram showing a pixel layout of a display device related to embodiment two of the present invention. A pixel arrangement of two rows and four columns is exemplified as a typical example in FIG. 7. In FIG. 7, a light emitting region of each pixel has a hexagonal shape and a layout is explained in which four pixels which each emit a different color light is counted as one unit.

Since the position of a pixel electrode and contact hole arranged in each pixel in pixel layout 30 shown in FIG. 7 is the same as in the pixel layout 20 shown in FIG. 2, this explanation is omitted here. In the pixel layout 30, the shape of a light emitting region is different compared to the pixel layout 20. Specifically, the first light emitting region 301, second light emitting region 302, third light emitting region 303 and fourth light emitting region 304 arranged in the first pixel 210, second pixel 220, third pixel 230 and fourth pixel 240 shown in the pixel layout 30 have a hexagonal shape. In other words, the shape of the each of the first to fourth light emitting regions (301 to 304) is a hexagonal shape in which the opposite corner parts 305, 306 of a rectangle or square are cut away. Although the first to fourth light emitting regions (301 to 304) have a substantially same shape in FIG. 7, each light emitting region may also have a different shape. In addition, the present invention is not limited to the shape shown in FIG. 7 and other hexagonal shapes are possible. In addition, other polygons are possible. Here, each inner angle of the polygon may be 90 degrees or more. By setting each inner angle of a polygon to 90 degrees or more, it is possible to control the shape in a photolithography process or etching process from changing from a design shape.

Here, the first end part 311 of the first light emitting region 301 and the second end part 312 of the second light emitting region 302 are non-parallel. In other words, the first end part 311 and the second end part 312 have non-parallel parts. In addition, in other words, the first end part 311 of the first light emitting region 301 and the second part 312 of the second light emitting region 302 facing in a row direction (D2 direction) are mutually non-parallel. In addition, in other words, the distances 315 and 316 between the first end part 311 and the second end part 312 in a different position in a column direction (D1 direction) are mutually different.

In addition, the second end part 312 and the third end part 313 of the third light emitting region 303 are non-parallel. In other words, the second end part 312 and third end part 313 have non-parallel parts. In addition, in other words, the second end part 312 of the second light emitting region 302 and the third end part 313 of the third light emitting region 303 facing in a column direction (D1 direction) are mutually non-parallel. In addition, in other words, the distances 317 and 318 between the second end part 312 and the third end part 313 in a different position in a row direction (D2 direction) are mutually different.

As described above, according to the light emitting type display device related to embodiment two, when the first end part 311 of the first light emitting region 301 and the second end part 312 of the second light emitting region 302 are non-parallel in adjacent pixels 210, 220, it is more difficult for the light which passes through the distance 316 which is longer than the distance 315 to reach the second end part 312 than the light passing through the distance 315 among the light output from the first end part 311 for example. Therefore, it is possible to control light output from the first end part 311 from reaching the second light emitting region 302. In addition, similarly, when the second end part 312 and the third end part 313 of the third light emitting region 303 are non-parallel, it is more difficult for the light which passes through the distance 318 which is longer than the distance 317 to reach the third end part 313 than the light passing through the distance 317 among the light output from the second end part 312 for example. Therefore, it is possible to control light output from the second part 312 from reaching the third light emitting region 303. As a result, it is possible to control leaking light or mixed colors from occurring between adjacent pixels. This effect is more particularly effective in the case where the color of light emitted by adjacent pixels is different.

### Modified Example of Embodiment Two

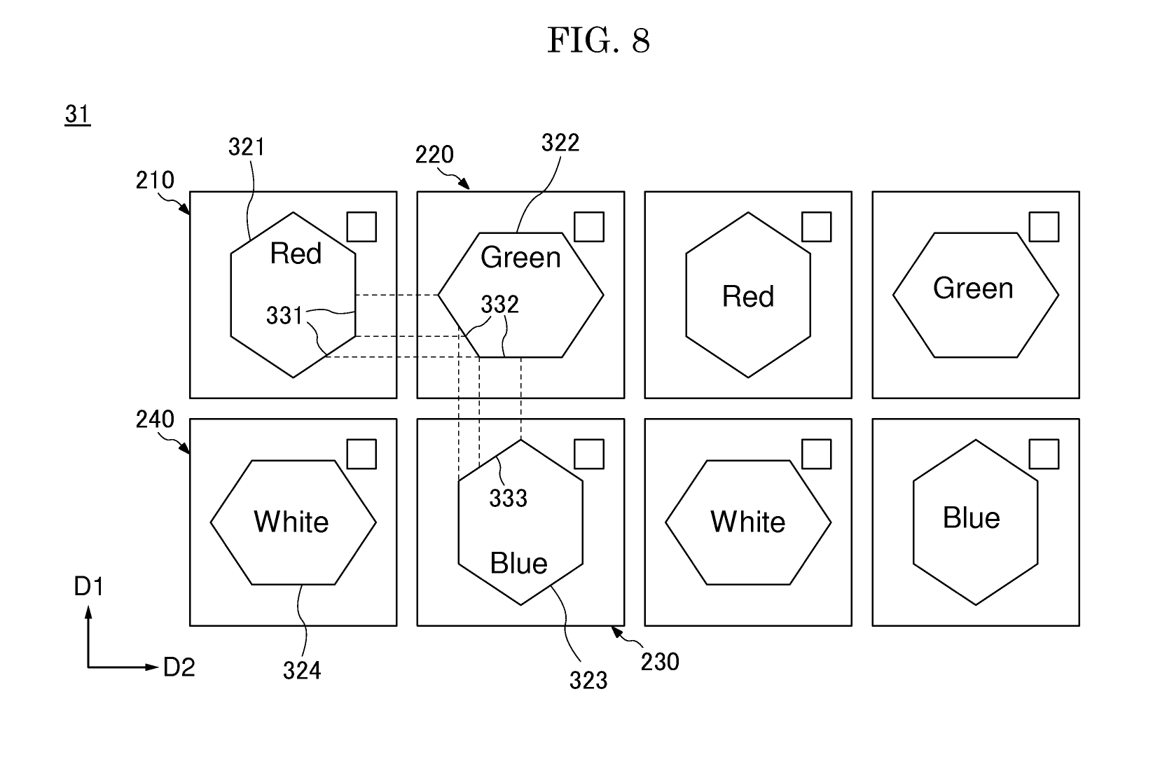

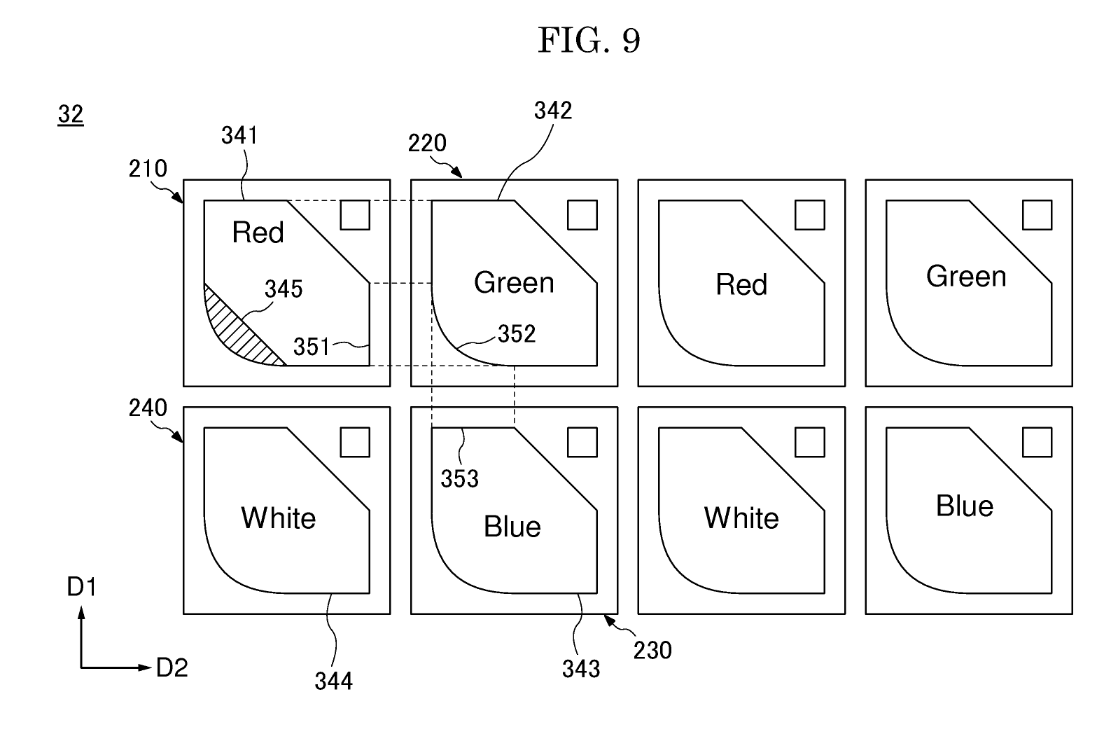

A pixel layout of a light emitting type display device relate to a modified example of embodiment two of the present invention is explained using FIG. 8 and FIG. 9. In the modified example, the display device 10 used in embodiment one is used and only the pixel layout is different.

FIG. 8 is a planar view diagram showing a pixel layout of a light emitting type display device related to a modified example 1 of embodiment two of the present invention. Although the pixel layout 31 shown in FIG. 8 is similar to the pixel layout shown 30 shown in FIG. 7, the pixel layout 31 is different to the pixel layout 30 in that the light emitting region of adjacent pixels in a row direction (D2 direction) and column direction (D1) has a 90 degree rotational shape.

As is shown in FIG. 8, the first light emitting region 321 and third light emitting region 323 arranged in the first pixel 210 and third pixel 230 shown in the pixel layout 31 have a shape in which a long side of a hexagon similar to the light emitting region of the pixel layout 30 extends in a column direction (D1 direction). In addition, the second light emitting region 322 and fourth light emitting region 324 arranged in the second pixel 220 and fourth pixel 240 have a shape in which a long side of the hexagon extends in a row direction (D2 direction). Although the first to fourth light emitting regions (321 to 324) have a rotational symmetrical shape or a substantially same shape in FIG. 8, each light emitting region may also have a different shape.

In the pixel layout 31 shown in FIG. 8, the first end part 331 of the first light emitting region 321 and the second end part 322 of the second light emitting region 322 are also non-parallel the same as the pixel layout 30 shown in FIG. 7. In addition, the second end part 332 and the third end part 333 of the third light emitting region 323 are non-parallel.

FIG. 9 is a planar view diagram showing a pixel layout of a light emitting type display device related to a modified example 2 of embodiment two of the present invention. Although the pixel layout 32 shown in FIG. 9 is similar to the pixel layout 30 shown in FIG. 7, the pixel layout 32 is different to the pixel layout 30 in that a part of the light emitting region of the light emitting region 30 has a curve.

As is shown in FIG. 9, the first light emitting region 341, second light emitting region 342, third light emitting region 343 and fourth light emitting region 344 arranged in the first pixel 210, second pixel 220, third pixel 230 and fourth pixel 240 shown in the pixel layout 32 have a shape in which a part of the end part of each light emitting region shown in FIG. 7 has a curved shape. As described above, when a part of an end part has a curved shape, the light emitting region in FIG. 9 has a wider area by the amount of the shaded part 345 compared to the light emitting region in FIG. 7. Although the first to fourth light emitting regions (341 to 344) have a substantially same shape in FIG. 9, each light emitting region may also have a different shape.

In the pixel layout 32 shown in FIG. 9, the first end part 351 of the first light emitting region 341 and the second end part 352 of the second light emitting region 342 are also non-parallel the same as the pixel layout 30 shown in FIG. 7. In addition, the second end part 352 and the third end part 353 of the third light emitting region 343 are non-parallel.

As described above, according to the light emitting type display device related to the modified example of embodiment two, when pairs of end parts of each light emitting region in adjacent pixels 210, 220 and adjacent pixels 220, 230 are non-parallel, it is possible to control light output from a light emitting region of the pixel 220, for example, from reaching the light emitting region of the first pixel 210 or third pixel 230. As a result, it is possible to control leaking light or mixed colors occurring between adjacent pixels.

### Embodiment Three

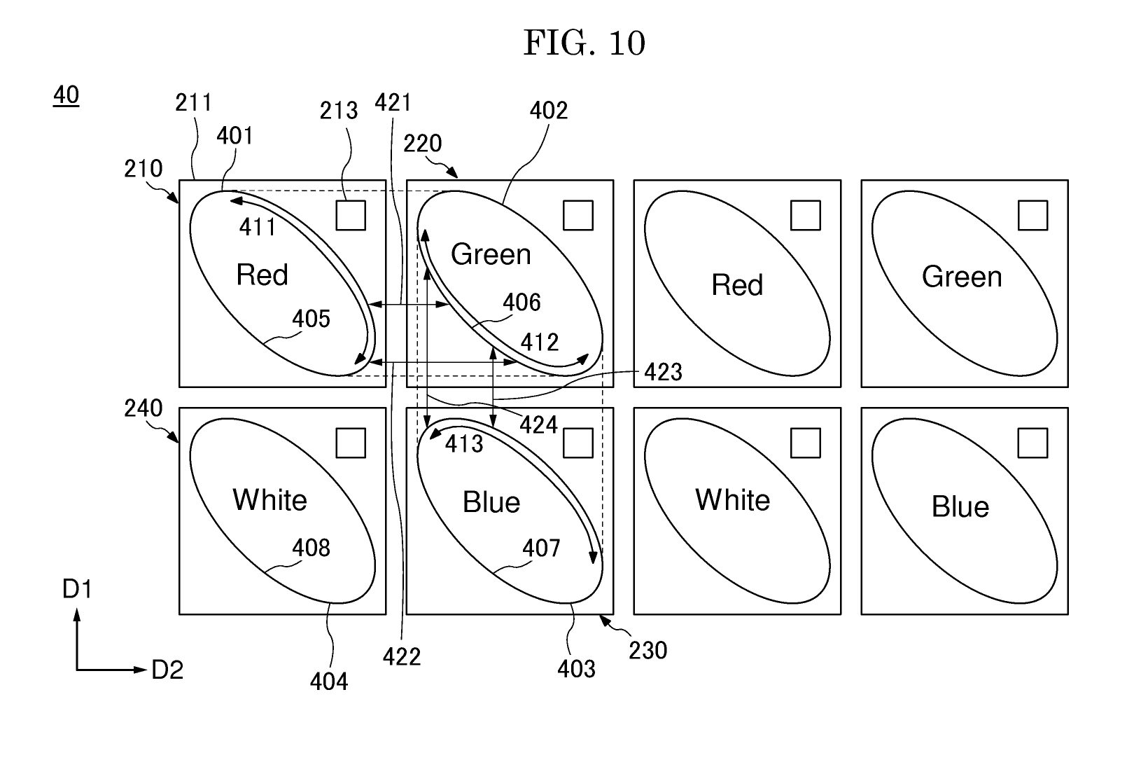

A pixel layout 40 of a light emitting type display device related to embodiment three of the present invention is explained using FIG. 10. Furthermore, the [white+CF structure] can be used for the light emitting type display device related to embodiment three the same as the display device 10 shown in FIG. 1.

### [Pixel Layout]

FIG. 10 is a planar view diagram showing a pixel layout of a display device related to embodiment three of the present invention. A pixel arrangement of two rows and four columns is exemplified as a typical example in FIG. 10. In FIG. 10, a light emitting region of each pixel has an ellipsoidal shape and a layout is explained in which four pixels which each emit a different color light is counted as one unit.

The pixel layout 40 shown in FIG. 10 has a different shaped light emitting region compared to the pixel layout 20. Specifically, the first light emitting region 401, second light emitting region 402, third light emitting region 403 and fourth light emitting region 404 arranged in the first pixel 210, second pixel 220, third pixel 230 and fourth pixel 240 shown in the pixel layout 40 have an ellipsoidal shape in which the long axis inclines in a direction which forms an angle of 45 degrees in a row direction (D2 direction) and column direction (D1 direction). Although the first to fourth light emitting regions (401 to 404) have a substantially same shape, each light emitting region may also have a different shape.

Here, when the positional relationship between the pixel electrode, light emitting region and contact hole of the pixel layout 40 is explained in detail using the first pixel 210, the first contact hole 213 is arranged adjacent to the light emitting region 401 in a short axis direction of the ellipsoidal shaped light emitting region 401 above the first pixel electrode 211. Here, the shape of the light emitting region is not limited to the shape shown in FIG. 10 and other circular or curved shapes are possible. As described above, by providing a light emitting region with an ellipsoidal shape, circular shape or curved shape, it is possible to control a shape from changing from a designed shape during a photolithography process or etching process.

Here, the first end part 411 which is a part of the end part facing the second pixel 220 side among the curved part 405 of the first light emitting region 401, and the second end part 412 which is a part of an end part facing the first pixel 210 side among the curved part 406 of the second light emitting region 402 are non-parallel. In other words, the first end part 411 and the second end part 412 have non-parallel parts. In addition, in other words, the first end part 411 of the first light emitting region 401 and the second end part 412 of the second light emitting region 402 facing in a row direction (D2 direction) are mutually non-parallel. In addition, in other words, the distances 421 and 422 between the first end part 411 and the second end part 412 in a different position in a column direction (D1 direction) are mutually different.

In addition, the second end part 412 and the third end part 413 which is a part of the end part facing the second pixel 220 side among the curved part 407 of the third light emitting region 403 are non-parallel. In other words, the second end part 412 and the third end part 413 have non-parallel parts. In addition, in other words, the second end part 412 of the second light emitting region 402 and the third end part 413 of the third light emitting region 403 facing in a column direction (D1 direction) are mutually non-parallel. In addition, in other words, the distances 423 and 424 between the second end part 412 and the third end part 413 in a different position in a row direction (D2 direction) are mutually different.

As described above, according to the light emitting type display device related to embodiment three, the first end part of the first light emitting region 401 and the second end part 412 of the second light emitting region 402 in adjacent pixels 210, 220 are non-parallel. Therefore, it is possible to control light output from the first end part 411 for example from reaching the second light emitting region 402. In addition, similarly, when the first end part 412 and the third end part 413 of the third light emitting region 403 in adjacent pixels 220, 230 are non-parallel, it is possible to control light output from the second end part 412 for example from reaching the third light emitting region 403. As a result, it is possible to control leaking light or mixed colors from occurring between adjacent pixels. This effect is particularly effective n the case where the color of emitted light by adjacent pixels is different.

### Embodiment Four

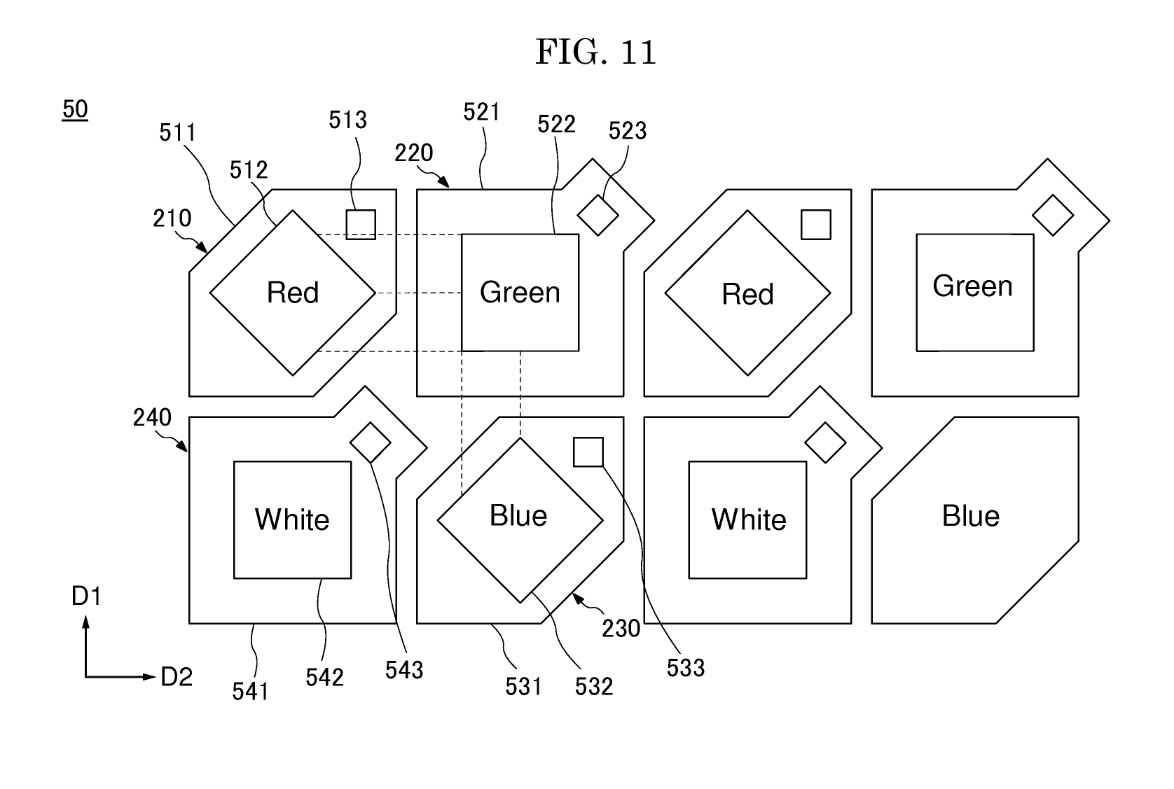

A pixel layout 50 of a light emitting type display device related to embodiment four of the present invention is explained using FIG. 11. Furthermore, the [white+CF structure] as the display device 10 shown in FIG. 1 can be used as the light emitting type display device related to embodiment four.

### [Pixel Layout]

FIG. 11 is a planar view diagram showing a pixel layout of a light emitting type display device related to embodiment four of the present invention. A pixel arrangement of two rows and four columns is exemplified as a typical example in FIG. 11. In FIG. 11, a light emitting region of each pixel has a four corner shape and a layout is explained in which four pixels which each emit a different color light is counted as one unit.

In the pixel layout 50 shown in FIG. 11, although the first light emitting region 512, second light emitting region 522, third light emitting region 532 and fourth light emitting region 542 arranged in the first pixel 210, second pixel 220, third pixel 230 and fourth pixel 240 have rotational symmetrical shape or a substantially same shape, light emitting regions adjacent in a row direction (D2 direction) and column direction (D1 direction) are rotated 45 degrees. Here, in the case of the second light emitting region 522 and fourth light emitting region 542, the direction in which a light emitting region faces can not be arranged similar to the second contact hole 223 and fourth contact hole 243 in FIG. 2 for example due to the effects of patterning design rules (margin between patterning). Therefore, the second contact hole 523 and fourth contact hole 543 is arranged as shown in FIG. 11. In line with this arrangement, the shape of the second pixel electrode 521 and fourth pixel electrode 541 which overlap the second contact hole 523 and fourth contact hole 543 is adjusted. In addition, in line with an adjustment of the shape of the second pixel electrode 521 and fourth pixel electrode 541, the shape of the first pixel electrode 511 and third pixel electrode 531 is also adjusted. As described above, the position of a contact hole and shape of a pixel electrode can be appropriately adjusted according to the shape and facing direction of a light emitting region.

As described above, according to the light emitting type display device related to embodiment four, it is possible to control leaking light or mixed color from occurring between adjacent pixels the same as in the first to fourth embodiments. In addition, since it is possible to appropriately change the position of a pixel electrode or contact hole according to the shape of each light emitting region, a design margin becomes wider.

### Embodiment Five

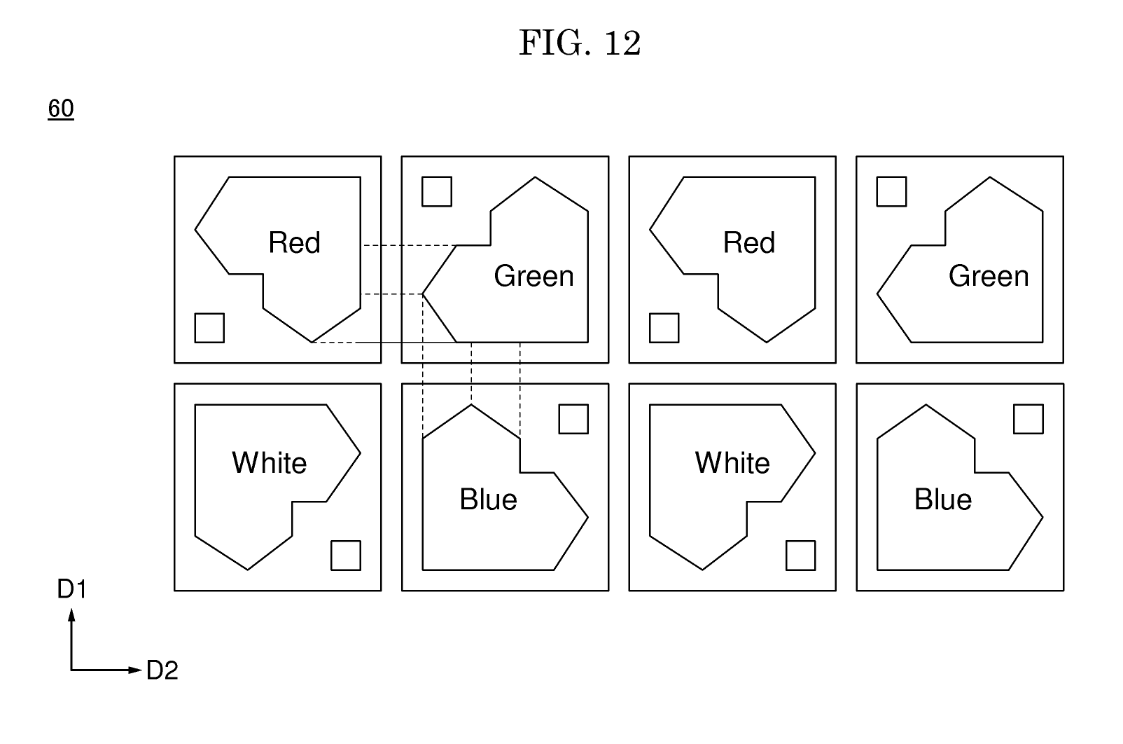

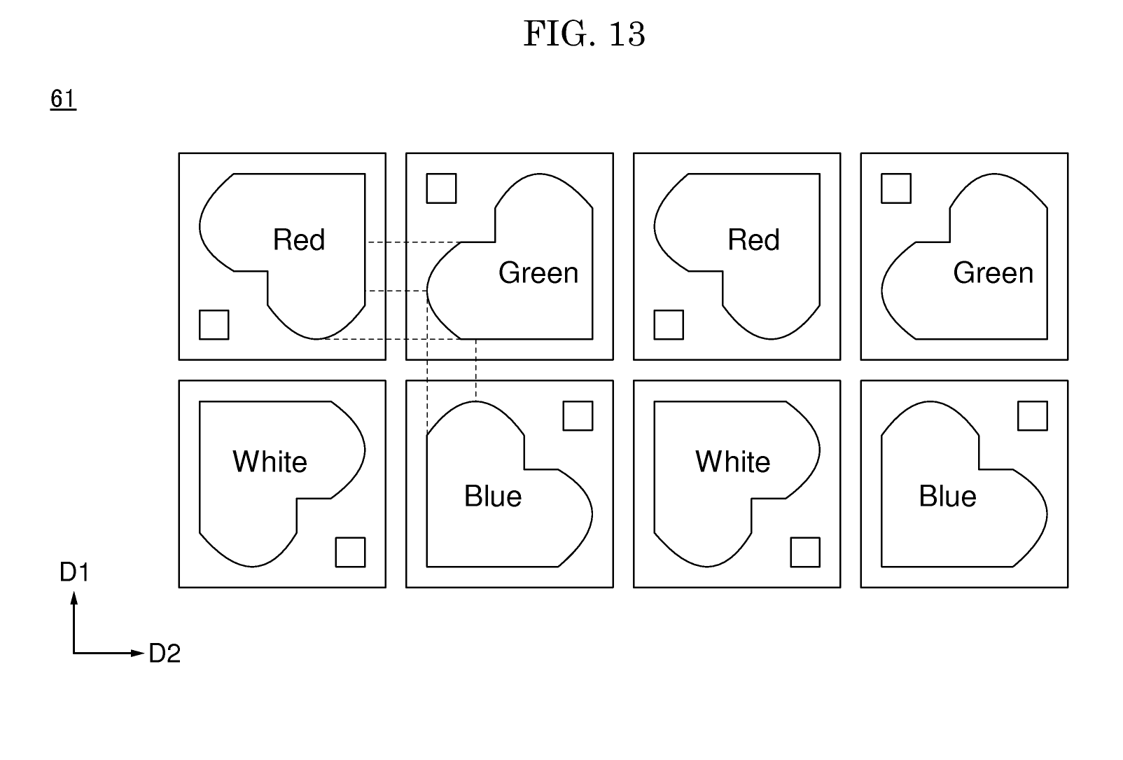

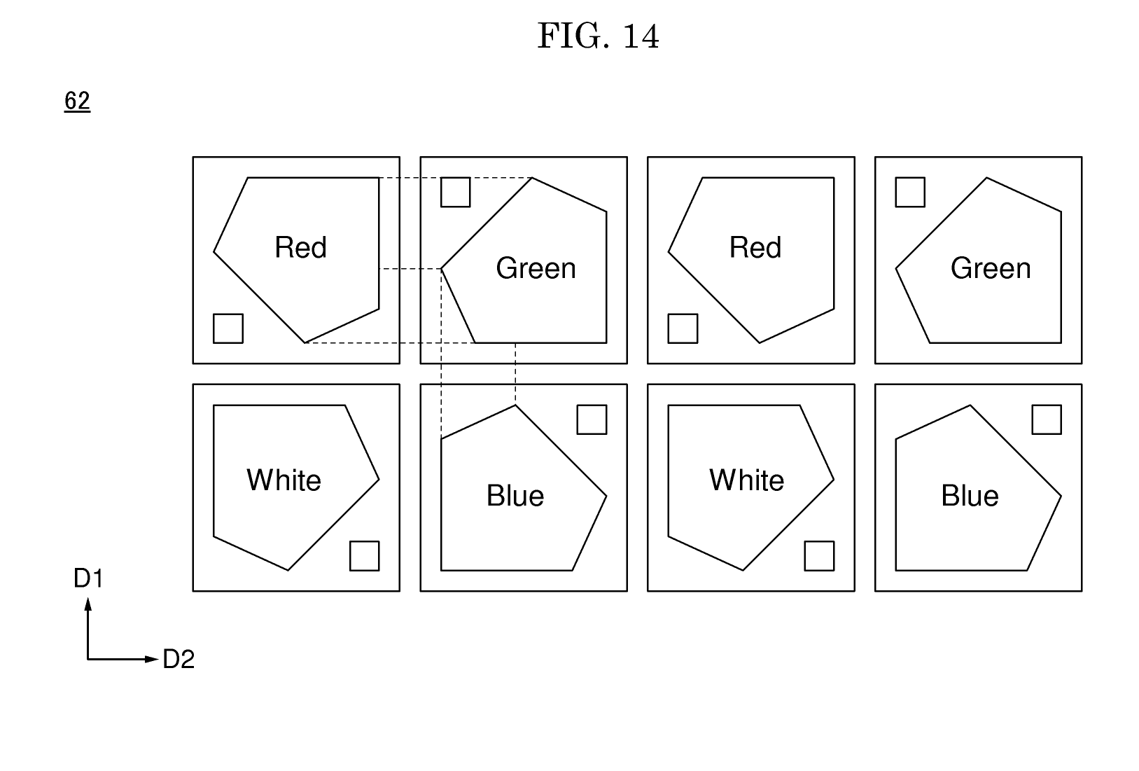

A pixel layout of a light emitting type display device related to embodiment five of the present invention is shown in FIG. 12 to FIG. 14. Furthermore, the [white+CF structure] as the display device 10 shown in FIG. 1 can be used as the light emitting type display device related to embodiment five. As is shown in FIG. 12 to FIG. 14, in the light emitting type display device related to the present invention, it is possible to make pairs of end parts of light emitting regions in adjacent pixels non-parallel using a polygon or a shape in which a part of a polygon is replaced with a curve. As a result, it is possible to control leaking light or mixed colors from occurring between adjacent pixels in any of the pixel layouts shown in FIG. 12 to FIG. 14. In addition, as is disclosed in the embodiments described previously, a method such as cutting away a peak part facing the edges of adjacent pixels or arranged a short edge part may be similarly applied to each pixel layout shown in FIG. 12 to FIG. 14.

### Comparative Example

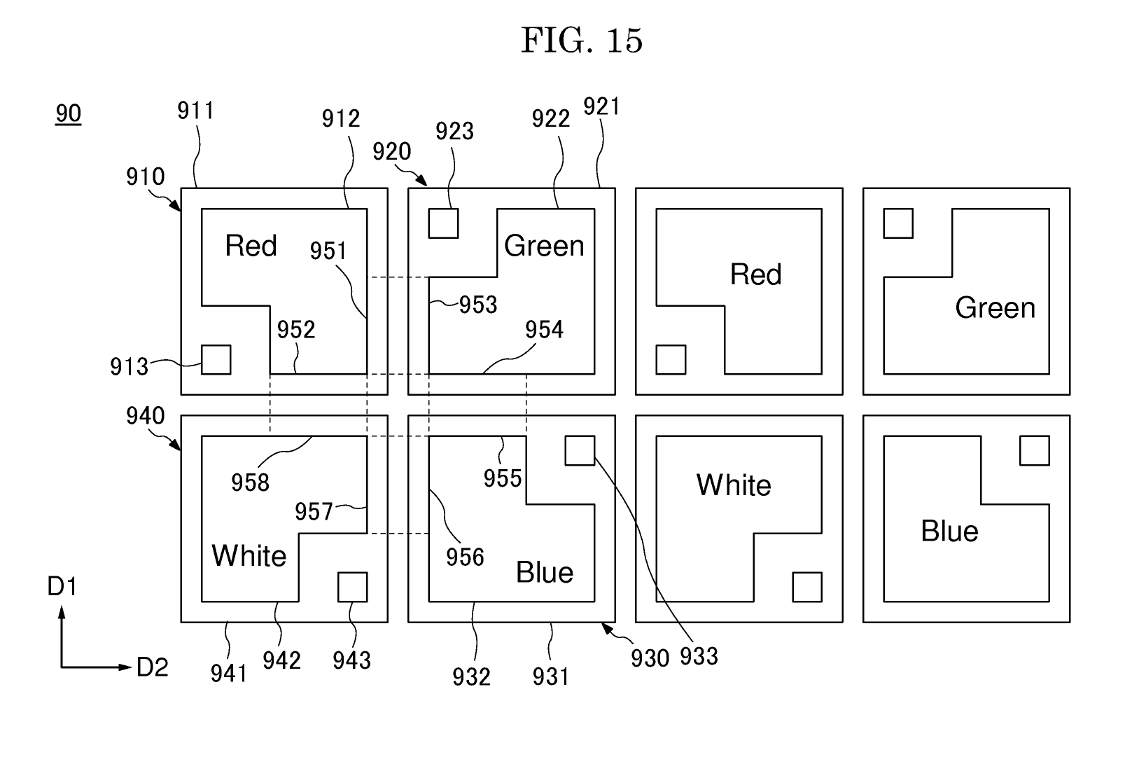

FIG. 15 is a planar view diagram showing a pixel layout of a light emitting type display device of a comparative example. A pixel arrangement of two rows and four columns is exemplified as a typical example in FIG. 15. In FIG. 15, a light emitting region of each pixel has an L character hexagonal shape and a layout is explained in which four pixels which each emit a different color light is counted as one unit.

The pixel layout 90 shown in FIG. 15 includes a first pixel 910, second pixel 920, third pixel 930 and fourth pixel 940. A first pixel electrode 911, first light emitting region 912 arranged with first end parts 951, 952, and a first contact hole 913 are arranged in the first pixel 910. In addition, a second pixel electrode 921, second light emitting region 922 arranged with second end parts 953, 954, and a second contact hole 923 are arranged in the second pixel 920. In addition, a third pixel electrode 931, third light emitting region 932 arranged with third end parts 955, 956, and a third contact hole 933 are arranged in the third pixel 930. In addition, a fourth pixel electrode 941, fourth light emitting region 942 arranged with fourth end parts 957, 958, and a fourth contact hole 943 are arranged in the fourth pixel 940.

Here, a part of the first end part 951 and the second end part 953 are parallel, a part of the second end part 954 and the third end part 955 are parallel, a part of the third end part 956 and the fourth end part 957 are parallel, and a part of the fourth end part 958 and the first end part 952 are parallel. For example, because the distance between the first end part 951 and second end part 953 in the adjacent first light emitting region 912 and second light emitting region 922 is close and the end parts are parallel, most of the light output from one of the light emitting regions reaches the other light emitting region which leads to the problem of leaking light and mixed colors.

Furthermore, the present invention is not limited to the embodiments described above and various modifications are possible without departing from the scope of the invention.

What is claimed is:

1. A display device having a plurality of pixels arranged in a matrix comprising:
a first pixel arranged with a first light emitting region including a first end part, the first pixel being arranged in a first column and first row of the matrix;
a second pixel arranged in adjacent in a row direction with the first pixel in a second column adjacent to the first column, the second pixel being arranged with a second light emitting region including a second end part, the first end part and second end part having a first non-parallel part; and
a third pixel arranged adjacent in a column direction with the second pixel in a second row adjacent to the first row, the third pixel being arranged with a third light emitting region including a third end part, the second end part and third end part having a second non-parallel part.

2. The display device according to claim 1, wherein the first light emitting region, the second light emitting region and third emitting region each emit light of a different color.

3. The display device according to claim 1, wherein the first light emitting region, the second light emitting region and third emitting region each have a substantially rotational symmetrical shape or a substantially same shape respectively.

4. The display device according to claim 2 further comprising:
A fourth pixel arranged with a fourth light emitting region, the fourth pixel being arranged in the first column and the second row;
wherein the fourth light emitting region emits light of a different color than the first light emitting region and the third emitting region.

5. The display device according to claim 4, wherein the first light emitting region, the second light emitting region, the third light emitting and the fourth light emitting region emit light in either red, green, blue or white respectively.

6. The display device according to claim 4, wherein the first light emitting region, the second light emitting region, the third light emitting and the fourth light emitting region have a substantially rotational symmetrical shape or a substantially same shape respectively.

7. The display device according to claim 1, wherein the second end part and the third end part have a planar part, and a region taken up by the planar part in a row direction is half that or less than a region taken up by the second non-parallel part.

8. The display device according to claim 1, wherein the first light emitting region, the second light emitting region and the third light emitting region are polygons respectively, and each inner angle of the polygon is 90 degrees or more.

9. The display device according to claim 1, wherein either the first end part, the second end part of the third end part has a curved part.

10. The display device according to claim 1, wherein the first light emitting region, the second light emitting region and the third light emitting region have an elliptical shape with a long axis inclining in the row direction and the column direction.

11. The display device according to claim 7, wherein the first light emitting region, the second light emitting region and the third light emitting region have a rotational symmetrical shape or the same shape respectively.

12. The display device according to claim 8, wherein the first light emitting region, the second light emitting region and the third light emitting region have a substantially rotational symmetrical shape or a substantially same shape respectively.

13. The display device according to claim 9, wherein the first light emitting region, the second light emitting region and the third light emitting region have a substantially rotational symmetrical shape or a substantially same shape respectively.

14. The display device according to claim 10, wherein the first light emitting region, the second light emitting region and the third light emitting region have a substantially rotational symmetrical shape or a substantially same shape respectively.
